(19) United States
(12) Patent Application Publication
(10) Pub. No.: US 2020/0323060 A1
(43) Pub. Date: Oct. 8, 2020

(54) CAMERA LIGHTING POWER SUPPLY

(71) Applicant: APTIV TECHNOLOGIES LIMITED, St Michael (BB)

(72) Inventors: Roman MAJERCZAK, Szczawnica (PL); Maciej BARSZCZOWSKI, Bielsko-Biala (PL)

(21) Appl. No.: 16/839,373

(22) Filed: Apr. 3, 2020

(30) Foreign Application Priority Data
Apr. 5, 2019 (FR) 1903663

(51) Int. Cl. H05B 45/32; H03K 3/35; B60R 11/04

(52) U.S. Cl. CPC H05B 45/32; B60R 11/04; H03K 3/35

(57) ABSTRACT

A pulsed power supply system for a vehicle vision sensor lighting device includes a pulsed power supply generator configured to electrically supply the lighting device, a linear DC voltage regulator configured to deliver a stabilized electrical voltage to the pulsed power supply generator from a variable electrical power source, and an amplifier configured to deliver an amplified electric current from the linear DC voltage regulator to the pulsed power supply generator.

### CROSS-REFERENCE TO RELATED APPLICATIONS

This application claims priority to French Patent Application No. 19 03663, filed Apr. 5, 2019.

### TECHNICAL FIELD

The present invention relates to the power supply of the lighting of a camera, more particularly to a pulsed power supply system for a vision sensor lighting device for a driver assistance system of a vehicle.

### BACKGROUND

The vehicles equipped with driver assistance systems generally include vision sensors, such as cameras, allowing night vision of obstacles or even road indications such as speed limit signs. It is important to be able to correctly detect these various elements, even in the event of reduced visibility so as to be able to trigger, if necessary, driver assistance devices.

Generally, onboard cameras include lighting devices that are part of the camera, such as infrared-type lighting. The power supply for this type of lighting generally comprises a switching power supply of the DC/DC converter type which allows stabilizing the lighting while providing it with sufficient power to supply the infrared light-emitting diodes with power lighting the area under camera control.

This type of power supply can cause distortions of images captured by the camera, the electronic image sensor circuit being generally sensitive to the electromagnetic emissions of the switching power supply. In addition, this type of power supply is bulky, which makes it difficult to miniaturize this type of night vision camera.

### SUMMARY

An illustrative example embodiment of a pulsed power supply system for a vehicle vision sensor lighting device includes a pulsed power supply generator configured to electrically supply the lighting device, a linear DC voltage regulator configured to deliver a stabilized electrical voltage to the pulsed power supply generator from a variable electrical power source, and an amplifier configured to deliver an amplified electric current from the linear DC voltage regulator to the pulsed power supply generator.

In addition, the system may include a unit for diagnosing the lighting device comprising a device for measuring the average amplified electric current and a device for comparing the average amplified electric current with a predetermined maximum current threshold so as to be able to detect an overconsumption defect of the lighting device. The system may also include a device for cutting off the power supply of the pulsed power supply generator configured to cut off the power supply of the pulsed power supply generator if the average amplified electric current is greater than the predetermined maximum current threshold.

The amplifier of the electric current can comprise a first bipolar transistor arranged in a Darlington topology with a second bipolar transistor, said second bipolar transistor being a bipolar transistor of the linear DC voltage regulator. The first bipolar transistor can include a characteristic of maximum collector current of at least 4 amperes, preferably 6 amperes. The first and second bipolar transistors can include a cut-off frequency ranging from 100 Hz to 100 MHz, preferably of at least 100 MHz.

An illustrative example embodiment of a vehicle vision sensor comprises the pulsed power supply system described above. The vision sensor may be a camera including the lighting system, the lighting system including a plurality of infrared light-emitting diodes so that the vehicle vision sensor is a camera with infrared lighting. The pulsed power supply system can be configured to provide pulsed current up to 100 MHz to the infrared light-emitting diodes.

Other objects and advantages of the present invention will become apparent from the following description.

Other characteristics, objects and advantages of at least one disclosed embodiment will become apparent upon reading the following detailed description and in relation to the appended drawings, given by way of non-limiting example.

### BRIEF DESCRIPTION OF THE DRAWING

FIG. 1 is a schematic block diagram of a pulsed power supply system of a lighting device of an onboard camera in a vehicle according to an embodiment of the invention.

### DETAILED DESCRIPTION

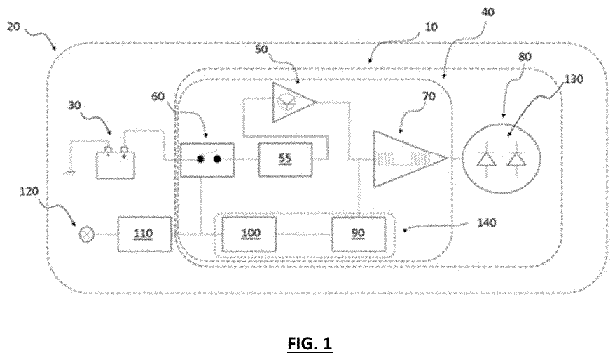

According to FIG. 1, a vehicle 20 is equipped with a camera 10 or vision sensor, allowing assistance in driving the vehicle 20. The camera 10 is electrically supplied by the battery 30 of the vehicle 10. The camera 10 comprises a lighting device 80 making it possible in particular to capture images in insufficient light conditions, such as during the night, or even when the vehicle 20 passes through the tunnel. Preferably, the lighting device 80 includes a plurality of light-emitting diodes 130 of the infrared type.

In order to limit the electrical consumption of the device, the camera 10 includes a pulsed power supply system 40 providing an electric current for a sufficient duration allowing the plurality of light-emitting diodes 130 of the infrared type to lighten the area to be illuminated, that is to say the speed limit signs, or obstacles in the path of the vehicle 20, and allowing the electronic image sensor circuit (not represented) of the camera 10 to capture the images necessary for the analysis of the area observed by the camera 10.

The pulsed power supply system 40 for the lighting device 80 of the camera 10 of the vehicle 20 includes a pulsed power supply generator 70 configured to electrically supply the lighting device 80.

In order to be able in particular to electrically supply the lighting device 80 including a plurality of light-emitting diodes 130 of the infrared type, the pulsed power supply generator 70 must be capable of providing at least 4 amperes, preferably 6 amperes, even 10 amperes in peak current. The pulsed power supply generator 70 must also be capable of pulsing the power supply up to a hundred Megahertz, in particular in the case of application of cameras 10 with the propagation time of the infrared light, commonly called ‘Time Of Flight Camera’. For applications of the camera driver monitoring types, a frequency of the order of a hundred Megahertz is sufficient to pulse the power supply of the lighting device 80 of the infrared type.

In order to provide a stabilized electrical voltage to the pulsed power supply generator 70, the pulsed power supply system 40 includes a linear DC voltage regulator 55 configured to deliver a stabilized electrical voltage to the pulsed power supply generator 70 from a variable electrical power source, in this case, from the battery 30 of the vehicle 20.

The use of a linear DC voltage regulator 55 instead of a switching power supply well known from the prior art of the infrared cameras, allows in particular overcoming the problems of electromagnetic emissions which can create the distortion of images captured by the camera. Preferably, the DC voltage regulator 55 is a serial-type linear voltage regulator, that is to say including a transistor providing the electric current to the pulsed power supply generator 70.

In order to be able to provide sufficient electric current to the pulsed power supply generator 70, the pulsed power supply system 40 includes an amplifier 50 of the electric current delivered by the linear DC voltage regulator 55 to the pulsed power supply generator 70, the amplifier 50 of the electric current being configured to deliver an amplified electric current to the pulsed power supply generator 70. Preferably, the amplifier 50 of the electric current comprises a first bipolar transistor arranged in a Darlington topology with a second bipolar transistor, said second bipolar transistor being a bipolar transistor of the serial-type linear DC voltage regulator.

In order to be able to correctly provide the electric current to the pulsed power supply generator 70, said pulsed power supply generator 70 being able to cause current draws of at least four amperes at a frequency of a hundred Megahertz, the first bipolar transistor and the second bipolar transistor comprise a cut-off frequency of at least 100 MHz.

In order to be able to diagnose a defect in the lighting device 80, the pulsed power supply system 40 comprises a unit 140 for diagnosing the lighting device 80 comprising a device 90 for measuring the average amplified electric current making it possible to measure the average value of the pulsed electric current consumed by the pulsed power supply generator 70, and a device 100 for comparing the average amplified electric current with a predetermined maximum current threshold so as to be able to detect an overconsumption defect of the lighting device 80.

Preferably, the device 90 for measuring the average amplified electric current includes a structure for measuring the current provided to the pulsed power supply generator 70 according to a current-mirror type topology. The image of the current provided to the pulsed power supply generator 70 circulating in the current-mirror is averaged by means of an electric circuit of series resistance and capacitor topology, the capacitor of which is connected to the electrical ground of the device.

The device 100 for comparing the average amplified electric current allows cutting off or authorizing the power supply of the lighting device 80 deactivating or activating the DC voltage regulator 55 by means of an electrical switch unit 60. Preferably, the DC voltage regulator 55 comprises a pin for activating or deactivating the voltage regulation so that it is not necessary to provide an additional electrical switch type unit 60.

The unit 140 for diagnosing the lighting device 80 is also electrically connected to a control unit 110 external to the camera 10 allowing in particular, by means of an indicator light 120 or other visual interface, to inform a user of the vehicle 20 of the failure of the lighting device 80 of the camera 10.

We claim:

1. A pulsed power supply system for a vehicle vision sensor lighting device, the system comprising:
a pulsed power supply generator configured to electrically supply the lighting device;
a linear DC voltage regulator configured to deliver a stabilized electrical voltage to the pulsed power supply generator from a variable electrical power source; and
an amplifier of electric current configured to deliver amplified electric current from the linear DC voltage regulator to the pulsed power supply generator.

2. The system according to claim 1 comprising a unit for diagnosing the lighting device comprising:
a device for measuring an average amplified electric current; and
a device for comparing the average amplified electric current with a predetermined maximum current threshold to detect an overconsumption defect of the lighting device.

3. The system according to claim 2 comprising a device configured to cut off the power supply of the pulsed power supply generator when the average amplified electric current is greater than the predetermined maximum current threshold.

4. The system according to claim 1, wherein the amplifier of the electric current comprises a first bipolar transistor arranged in a Darlington topology with a second bipolar transistor, said second bipolar transistor being a bipolar transistor of the linear DC voltage regulator.

5. The system according to claim 4, wherein the first bipolar transistor includes a characteristic of maximum collector current of at least 4 amperes.

6. The system according to claim 4 wherein, the first and second bipolar transistors include a cut-off frequency of at least 100 MHz.

7. A vehicle vision sensor comprising the pulsed power supply system according to claim 1.

8. The sensor according to claim 7, comprising the lighting system.

9. The sensor according to claim 8, wherein the lighting system includes a plurality of infrared light-emitting diodes.

10. The sensor according to claim 9, wherein the pulsed power supply system is configured to provide a pulsed current up to 100 MHz to the infrared light-emitting diodes.
